(19) United States
(12) Patent Application Publication
(10) Pub. No.: US 2011/0155222 A1
(43) Pub. Date: Jun. 30, 2011

(54) LIGHT, RIGID, SELF-SUPPORTING SOLAR MODULE AND METHOD FOR THE PRODUCTION THEREOF

(75) Inventors: Hubert Ehbing, Odenthal (DE); Gunther Stollwerck, Krefeld (DE); Dirk Wegener, Monheim (DE); Jens Krause, Mours-Saint-Eusebe (FR); Elke Springer, Leverkusen (DE); Heike Schmidt, Leverkusen (DE); Frank Schauseil, Leverkusen (DE)

(73) Assignee: Bayer MaterialScience AG, Leverkusen (DE)

(21) Appl. No.: 12/997,710

(22) PCT Filed: Jun. 12, 2009
(86) PCT No.: PCT/EP2009/003951

§ 371 Date: Mar. 4, 2011

(30) Foreign Application Priority Data
Jun. 12, 2008 (DE) 10 2008 028 069.0
Mar. 21, 2009 (DE) 10 2009 014 348.3

(51) Int. Cl. H01L 31/048; B29C 65/02; B32B 37/12; B32B 37/10; H01L 31/18

(52) U.S. Cl. 136/251; 156/285; 156/60; 156/182

(57) ABSTRACT

The solar module according to the invention consists of a transparent adhesive layer (1), in which the solar cells (3) that are interconnected by cell connectors (2) are embedded. A transparent, UV stable, thin front layer (4), composed for example of a thin pane of glass, is located above said adhesive layer. The supporting sandwich element (5), consisting of a nucleic layer (6) and glass fibre layers (7) bonded by means of polyurethane is located on the rear face. Fastening elements (8) and an electric socket (9) are integrated into the supporting sandwich element. A barrier film (10), which prevents the entry of water and oxygen, adjoins the sandwich element. The solar module has peripheral edge protection (11) consisting of elastomeric polyurethane, which prevents the lateral penetration of water, dirt and oxygen. The invention also relates to a method for producing the solar module.

The present invention relates to a photovoltaic solar module and to a method for the production thereof.

The term solar modules refers to components for the direct generation of electrical current from sunlight. Key factors for the cost-efficient generation of solar electricity are the efficiency of the solar cells used, as well as the production costs and durability of the solar modules.

A solar module conventionally consists of a framed assembly of glass, interconnected solar cells, an embedding material and a backside structure. The individual layers of the solar module have to fulfil the following functions.

The front glass is used to protect against mechanical and weathering effects. It must have the highest of transparencies in order to minimise absorption losses in the optical spectral range of from 300 nm to 1150 nm and therefore efficiency losses of the silicon solar cells conventionally used for the electricity generation. Low-iron toughened white glass (3 or 4 mm thick) is normally used, the transmissivity of which is from 90 to 92% in the aforementioned spectral range. The glass furthermore makes a significant contribution to the rigidity of the module.

The embedding material (EVA (ethylene vinyl acetate) sheets are mostly used) is used to bond the entire module assembly. EVA melts at about 150° C. during a lamination process, flows into the gaps of the soldered solar cells and is thermally crosslinked. Formation of air bubbles, which lead to reflection losses, is avoided by lamination in a vacuum.

The module backside protects the solar cells and the embedding material against moisture and oxygen. It furthermore serves as mechanical protection against scratching etc. when the solar modules are being fitted, and as electrical insulation. A further glass plate or a composite sheet may be used as a backside structure. Essentially, the variants PVF (polyvinyl fluoride)-PET (polyethylene terephthalate)-PVF or PVF-aluminium-PVF are used for this.

The encapsulation materials used in solar module construction must in particular have good barrier properties against water vapour and oxygen. The solar cells themselves are not attacked by water vapour or oxygen, but corrosion of the metal contacts and chemical degradation of the EVA embedding material takes place. A broken solar cell contact leads to complete failure of the module, since normally the solar cells in a module are electrically connected in series. Degradation of EVA is manifested by yellowing of the module, associated with a corresponding performance reduction due to light absorption as well as visual deterioration. Nowadays, about 80% of all modules are encapsulated with one of the aforementioned composite sheets on the backside, and in about 15% of solar modules glass is used for the front side and backside. In this case, highly transparent but only slowly (several hours) curing casting resins are sometimes used as an embedding material instead of EVA.

In order to achieve competitive electricity generation costs of solar electricity despite the relatively high investment costs, solar modules must achieve long operating times. Modern solar modules are therefore configured for a lifetime of from 20 to 30 years. Besides high weathering stability, great demands are placed on the thermal endurance of the modules, the temperature of which may vary during operation cyclically between 80° C. with full insolation and temperatures below freezing point. Accordingly, solar modules are subjected to comprehensive stability tests (standard tests according to IEC 61215 and IEC 61730), which include weathering tests (UV irradiation, damp heat, temperature cycle) but also hail tests and tests of the thermal insulation capacity.

At 30% of the total cost, the final module fabrication makes up a relatively high proportion of the total costs for photovoltaic modules. This large fraction for module fabrication is due to high material costs (for example multilayer backside sheet) and long process times, i.e. low productivity. Even now, the above-described individual layers of the module assembly are often put together and adjusted by manual work. Furthermore, the relatively slow melting of the EVA hot-melt adhesive and the lamination of the module assembly at about 150° C. and in a vacuum leads to a cycle times of about 20 to 30 minutes per module.

Owing to the relatively thick front glass plate, conventional solar modules also have a high weight, which in turn necessitates stable and expensive holding structures. Furthermore, thermal dissipation in modern solar modules has only been achieved unsatisfactorily. Under full insolation, the modules are heated to up to 80° C., which leads to thermally induced deterioration of the solar cell efficiency and therefore in the end to an increased cost of the solar electricity.

In the prior art, solar modules with an aluminium frame are predominantly used. Although this is a light metal, its weight still makes a non-negligible contribution to the total weight. Particularly for larger modules, this is a disadvantage which necessitates elaborate holding and fastening structures.

In order to prevent ingress of water and oxygen, the said aluminium frames have an additional seal on their inner side facing towards the solar module. Another disadvantage is that aluminium frames are made from rectangular profiled sections, and there are therefore great restrictions in respect of shaping them.

In order to reduce the solar module weight, obviate an additional sealing material and increase the design freedom, U.S. Pat. No. 4,830,038 and U.S. Pat. No. 5,008,062 describe the application of a plastic frame around the solar module in question, this frame being obtained by the RIM (Reaction Injection Moulding) method.

The polymer material used is preferably an elastomeric polyurethane. The said polyurethane should preferably have an E modulus in a range of from 200 to 10,000 p.s.i. (corresponding to about 1.4 to 69.0 N/mm²).

In order to strengthen the frame, various options are described in these two patent specifications. For instance, reinforcing components made for example of a polymer material, steel or aluminium may also be integrated into the frame when it is being made. Fillers may also be introduced into the frame material. These may, for example, be fillers in platelet form such as the mineral wollastonite, or fillers in needle/fibre form such as glass fibres.

Similarly, DE 37 37 183 A1 likewise describes a method for producing the plastic frame of a solar module, the Shore hardness of the material used preferably being adjusted so as to ensure sufficient rigidity of the frame and resilient holding of the solar generator.

The modules described above are set up with the aid of supporting structures or, for example, applied onto roof structures. To this end, they require a certain module rigidity, which is disadvantageously obtained by a (plastic) frame and the relatively heavy front a plate, which is about 3 to 4 mm thick. Furthermore, merely because of its thickness, the front plate has a certain absorption which in turn has a detrimental effect on the efficiency of the solar module.

The term sheet modules refers to the embedding of solar cells between two plastic sheets, and optionally between a transparent sheet on the front side and a flexible metal sheet (aluminium or stainless steel) on the backside. For example, sheet laminates of the brand “UNIsolar®” consist of amorphous thin-film silicon evaporated onto a thin stainless steel sheet and embedded between two plastic sheets. These flexible laminates must then be adhesively bonded onto a rigid bearing structure, for example metal roofing sheets or roofing elements made of metal sandwich composites. DE 10 2005 032 716 A1 describes a flexible solar module which must subsequently be applied on a rigid bearing structure. A disadvantage here is the additional working step of subsequent adhesive bonding to a bearing structure.

Owing to the different thermal expansion coefficients of the plastic frame and the glass, delaminations have repeatedly occurred in the past together with ingress of moisture into the inner region of the solar module, which finally have led to destruction of the module.

It is therefore an object of the present invention to provide a solar module which avoids these disadvantages of the prior art.

The solar module should have a weight per unit area which is as low as possible and at the same time be as rigid as possible, so as to require no bearing or fastening structure or only a very simple one, and to easy to handle. The solar module should furthermore have a sufficient long-term assembly stability, which prevents delamination and/or ingress of moisture.

This object is achieved by the photovoltaic solar module according to the invention.

The invention provides a solar module having a structural configuration consisting of
a) a transparent layer A), in the form of a glass plate or a plastic layer, facing towards the light source,
b) an adhesive layer B) as an interlayer and solar cells embedded in it,
c) a sandwich element C) consisting of at least one core layer and at least one outer layer lying on either side of the core layer, optionally having fastening and electrical connection elements.

It has surprisingly been found that a photovoltaic solar module having such a structural configuration inherently combines the desired properties.

Owing to its sufficiently high rigidity, such a structure has a sufficiently high stability. As a result of this sufficiently high rigidity, the solar module is easy to handle and does not bend even after a prolonged period of time (for example when applied with a spacing on non-vertical surfaces).

Furthermore, the difference of the thermal expansion coefficient of the sandwich element C) in relation to the transparent layer A) and the solar cell is very small, so that scarcely any mechanical stresses occur and the risk of delamination is very small.

The sandwich element C) of the solar module according to the invention furthermore serves to the seal the solar module against external influences.

With an additional barrier layer, for example in the form of a barrier sheet, this sealing can be optimised further. It is preferably applied directly during production of the sandwich element, and may lie either on the sandwich element's side facing towards the adhesive layer or between the adhesive layer and the sandwich element. The barrier sheet may, for example, be placed in the pressing tool before the sandwich element is introduced. The barrier layer may also be produced by in-mould coating, by spraying the barrier layer into the pressing tool before the sandwich element is introduced. As an alternative, the barrier layer may also be adhesively bonded onto the sandwich element afterwards. It is likewise possible to spray a barrier layer subsequently over the sandwich element.

The solar module may furthermore be fastened onto the respective base (for example house roofs or walls) by means of the sandwich element C). The solar module therefore preferably has fastening means, recesses and/or holes, already integrated in the sandwich element, by means of which application onto the respective base can be carried out. The sandwich element furthermore preferably contains the electrical connection elements, so that subsequent application of for example connection boxes can be obviated.

The sandwich element C) is preferably based on polyurethane (PUR), since particularly high rigidities are thereby obtained. Such a sandwich element C) consists of a core layer and fibre layers, which are impregnated with a polyurethane resin, applied on both sides of the core layer. In order to produce the sandwich element with the described structure, the known methods may be envisaged: NafpurTec method, LFI/FipurTec method or Interwet method, CSM method and lamination method.

The polyurethane resin used may be obtained by reacting
1) at least one polyisocyanate,
2) at least one polyol component having an average OH number of from 300 to 700, which contains at least one short-chain polyol and one long-chain polyol, the starting polyols having a functionality of from 2 to 6,
3) water,
4) activators,
5) stabilisers,
6) optionally auxiliary substances, release agents and/or additives.

As long-chain polyols, polyols having from at least two to at most six H atoms that are reactive in relation to isocyanate groups are preferably used; polyester polyols and polyether polyols which have OH numbers of from 5 to 100, preferably from 20 to 70, particularly preferably from 28 to 56, are preferably used.

The short-chain polyols are preferably ones which have OH numbers of from 150 to 2000, preferably from 250 to 1500, particularly preferably from 300 to 1100.

According to the invention higher-ringed isocyanates of the diphenylmethane diisocyanate series (pMDI types), prepolymers thereof or mixtures of these components are preferably suitable.

Water is used in amounts of from 0 to 3.0, preferably from 0 to 2.0 parts by weight per 100 parts by weight of polyol formulation (components 2) to 6)).

The activators which are conventional per se for the blowing and crosslinking reactions, for example amines or metal salts, are used for catalysis.

Polyether siloxanes, preferably water-soluble components, may preferably be envisaged as foam stabilisers. The stabilisers are conventionally used in amounts of from 0.01 to 5 parts by weight, expressed in terms of 100 parts by weight of the polyol formulation (components 2) to 6)).

Auxiliary substances, release agents and additives may optionally be added to the reaction mixture for producing the polyurethane resin, for example surface-active additives, for example emulsifiers, flameproofing agents, nucleation agents, oxidation retardants, lubricants and mould release agents, dyes, dispersants, blowing agents and pigments.

The components are made to react in amounts such that the equivalence ratio of the NCO groups of the polyisocyanates 1) to the sum of the hydrogens, which are reactive in relation to isocyanate groups, in components 2) and 3) and optionally 4), 5) and 6) is from 0.8:1 to 1.4:1, preferably from 0.9:1 to 1.3:1.

Materials which may be used for the core layer of the sandwich element C) are for example hard foams, preferably polyurethane (PUR) or polystyrene foams, balsa wood, corrugated sheet metal, spacers (for example large-pored open plastic foams), honeycomb structures, for example made of metals, impregnated paper or plastics, or sandwich core materials known from the prior art (for example Klein, B., Leichtbau-Konstruktion, Verlag Vieweg, Braunschweig/Wiesbaden, 2000, pages 186 ff.). Formable, in particular thermoformable hard foams (for example PUR hard foams) and honeycomb structures, which allow curved or three-dimensional shaping of the solar module which is to be produced, are also particularly preferred. Furthermore, hard foams with good insulation properties are especially preferred. The element C), in particular the core layer, is also used for insulation, in particular thermal insulation.

As a fibre material for the fibre layers, it is possible to use glass fibre mats, glass fibre nonwovens, chopped glass fibre strands, glass fibre fabrics, cut or ground glass or mineral fibres, natural fibre mats and knits, cut natural fibres, and fibre mats, nonwovens and knits based on polymer, carbon or aramid fibres, and mixtures thereof.

Production of the sandwich elements C) may be carried out by initially placing a fibre layer, to which the polyurethane starting components 1) to 6) are applied, on both sides of the core layer. As an alternative, the fibre reinforcing substance may also be introduced with the polyurethane raw materials 1) to 6) by a suitable mixing head technique. The preform produced in this way, consisting of the three layers, is transferred into a moulding tool and the mould is closed. The individual layers are bonded together by the reaction of the PUR components.

The sandwich element C) is distinguished by a low weight per unit area of from 1500 to 4000 g/m² and a high rigidity of from 0.5 to 5×10⁶ N/mm² (for a sample width of 10 mm). In particular, the sandwich element has a significantly lower weight per unit area in comparison with other bearing structures made of plastics or metals, for example plastic blends (polycarbonate/acrylonitrile-butadiene-styrene, polyphenylene oxide/polyamide), sheet moulding compound (SMC) or sheet aluminium and steel with a comparable rigidity.

The transparent layer A) may consist of the following materials: glass, polycarbonate, polyester, polymethyl methacrylate, polyvinyl chloride, fluorinated polymers, epoxides, thermoplastic polyurethanes or any desired combinations of these materials. Transparent polyurethanes based on aliphatic isocyanates may furthermore be used. HDI (hexamethylene diisocyanate), IPDI (isophorone diisocyanate) and/or H12-MDI (saturated methylene diphenyl diisocyanate) may be employed as isocyanates. Polyethers and/or polyester polyols may be used as polyol components, as well as a chain extenders, aliphatic systems preferably being used.

The layer A) may be configured as a plate, sheet or composite sheet. A transparent protective layer may preferably also be applied onto the transparent layer A), for example in the form of a lacquer or a plasma layer. The transparent layer A) can be made softer by such a measure, so that stresses in the module can be reduced further. The additional protective layer would undertake protection against external influences.

The adhesive layer B) has the following properties: high transparency in the range of from 350 nm to 1150 nm, good adhesion to silicon and to the material of the transparent layer A) and to the sandwich element C). The adhesive layer may consist of one or more adhesive sheets, which are laminated onto the layer A) and/or the sandwich element.

The adhesive layer B) is soft in order to compensate for the stresses which occur owing to the different thermal expansion coefficients of the transparent layer A), solar cells and sandwich element C). The adhesive layer B) preferably consists of a thermoplastic polyurethane, which may optionally be coloured.

The thermal expansion coefficient of the sandwich element C is preferably from 10 to 20×10⁻⁶ K⁻¹, depending on the sandwich composition and the fibre reinforcement.

The solar module preferably has a circumferential polyurethane frame, which may be applied subsequently by RIM, R-RIM, S-RIM, RTM, spraying or casting.

The invention furthermore provides a method for producing the solar modules according to the invention, characterised in that
i) a sandwich element C) consisting of at least one core layer and at least one outer layer lying on either side of the core layer, and optionally having fastening and electrical connection elements, is provided,
ii) an adhesive layer B) is applied in the form of a plastic sheet or as a compound onto the sandwich element C),
iii) the solar cells are placed on the adhesive layer B) or embedded in the adhesive layer B), or a solar sheet is applied onto the adhesive layer B),
iv) a transparent plastic sheet, which optionally comprises an adhesive layer B), and/or a transparent layer A) is applied onto solar cells,
v) the said layer structure is optionally pressed, optionally under the effect of temperature and/or optionally while applying a vacuum.

The sandwich element C) may be provided as an already pressed or bonded sandwich element, or as an unbonded sandwich element in which the layers have not yet been pressed or bonded.

The method may also be carried out by initially providing the transparent layer A) (for example a plastic sheet). An adhesive layer B) in the form of a plastic sheet or as a compound is subsequently applied onto the layer A). The solar cells or the solar sheet are placed on the adhesive layer B) or embedded in the adhesive layer B). A sandwich element C), which optionally comprises an adhesive layer B), is then applied. Preferably, pressing is subsequently carried out optionally under the effect of temperature.

The method may also be configured so that a finished sheet module consisting of the layers A) and B), which already comprises the solar cells or the solar layer, is placed in a pressing tool. This sheet module preferably has an adhesive layer B), preferably made of thermoplastic polyurethane, on the side facing towards the sandwich element to be applied.

As an alternative, an as yet unbonded sheet module may be prepared by initially providing a transparent layer A). An adhesive layer B) in the form of a plastic sheet or as a compound is subsequently applied onto the transparent layer A). The solar cells or the solar sheet are thereupon placed on the adhesive layer B) or embedded in the adhesive layer B). A further adhesive layer B)—preferably made of a thermoplastic polyurethane—is then optionally applied.

A likewise preferably not yet pressed sandwich element (preferably a PUR sandwich) is then placed on the already bonded sheet module which is provided, or on the sheet module which is only prepared but not yet bonded. Pressing is subsequently carried out, optionally while increasing the temperature. The pressing process cures the sandwich element and bonds it in the same working step to the sheet module. If an as yet unbonded sheet module is provided, the pressing process simultaneously serves to bond the laminate layers together.

In addition, further functional layers and elements may be introduced before the pressing process and bonded to the solar module by the pressing process. For example, a barrier sheet against oxygen and moisture (for example PVF (polyvinyl fluoride)-PET (polyethylene terephthalate)-PVF or PVF-aluminium-PVF composite sheets) may be introduced between the layer B) and the sandwich element C). These barrier sheets optionally in turn comprise an adhesive layer for good bonding to the sandwich element C). As an alternative, these barrier layers may also be applied onto the backside (the side facing away from the light) of the sandwich element C). In order to improve the thermal insulation, it is furthermore possible to apply an additional insulation layer, for example made of a polyurethane hard foam, onto the backside of the sandwich element C).

In a further embodiment, media lines may also be pressed in when producing the sandwich element C). These lines may for example consist of plastic or copper. These lines are preferably placed close to the layer B) and can be used to cool the solar module by means of a medium (for example water) which transports heat away. The electrical efficiency can be increased by internal cooling of the solar module.

The solar modules according to the invention generate electricity and simultaneously act as an insulation layer, so that they can also be used well as roof cladding. They are very lightweight and at the same time rigid. They can also be converted into three-dimensional structures by pressing, so that they can be adapted well to predetermined roof structures.

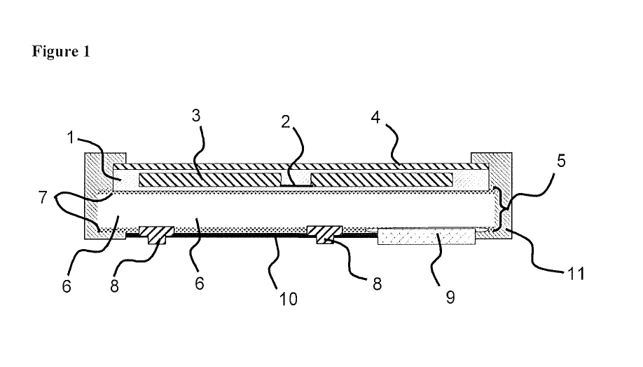

The invention will be explained in more detail by way of example with the aid of appended FIG. 1. In FIG. 1, the arrangement consists of a transparent adhesive layer 1 in which the solar cells 3, connected by means of cell connectors 2, are embedded. On top of this there is a transparent, UV-stable thin front layer 4, for example consisting of a thin glass plate. On the backside there is the supporting sandwich element 5, consisting of a core layer 6 and glass fibre layers 7 bonded by polyurethane. Fastening elements 8 and an electrical connection box 9 are integrated into the supporting sandwich element. The sandwich element is followed by a barrier sheet 10, which prevents ingress of water and oxygen. The solar module has circumferential edge protection 11 made of elastomeric polyurethane, which prevents lateral ingress of water, dirt and oxygen.

### EXAMPLE

A solar module was fabricated from the following individual components. A 125 μm thick polycarbonate sheet (of the type Makrofol® DE 1-4 from Bayer MaterialScience AG, Leverkusen) was used as the front layer. Two 480 μm thick EVA sheets (of the type Vistasolar® from the company Etimex, Rottenacker) were used as adhesive layers. A Baypreg® sandwich was used as the sandwich element. To this end, a honeycomb paperboard of the type Testliner 2 (A-wave, paperboard thickness 4.9-5.1 mm from the company Wabenfarbik, Chemnitz) was provided on both sides with a chopped fibre mat of the type M 123 having a weight per unit area of 300 g/m² (from the company Vetrotex, Herzogenrath). On this structure, 300 g/m² of a reactive polyurethane system were subsequently sprayed using a high-pressure processing machine. A polyurethane system from Bayer MaterialScience AG, Leverkusen was used, consisting of a polyol (Baypreg® VP.PU 011F13) and an isocyanate (Desmodur® VP.PU 08IF01) in the mixing ratio 100 to 235.7 (index 129). The structure consisting of the honeycomb paperboard and the chopped fibre mats sprayed with polyurethane was pressed for 90 seconds in a tool regulated to 130° C. in order to form a 10 mm thick Baypreg® sandwich composite.

The individual components in the order polycarbonate sheet, EVA sheet, 4 silicon solar cells, EVA sheet and finally the Baypreg® sandwich were assembled to form a laminate and initially evacuated for 6 minutes in a vacuum laminator (company NPC, Tokyo, Japan) at 150° C. and then pressed for 7 minutes at a pressure of 1 bar to form a solar module.

The solar module produced in this way was analysed in a solar simulator under a standard spectrum (AM 1.5 g conditions). The unweathered module had an efficiency of 13.4% (+/−0.5%). Based on IEC 61215, a climate cycle test was subsequently carried out with the module. 302 climate change cycles (between −40° C. and +85° C.) were executed. After this weathering, the efficiency measured in the solar simulator was 12.8% (+/−0.5%).

1.-7. (canceled)

8. A Solar module comprising:
a) a transparent layer (A), in the form of a glass plate or a plastic layer, facing towards a light source;
b) an adhesive layer (B) as an interlayer, wherein solar cells are embedded in the adhesive layer; and
c) a sandwich element (C), comprising at least one core layer and at least one outer layer lying on either side of the core layer.

9. The solar module according to claim 1, wherein the sandwich element further comprises fastening and electrical connection elements.

10. The solar module according to claim 1, characterised in that the layer structure comprises a plastic frame.

11. A method for producing a solar module according to claim 1, the method comprising:
i) a sandwich element C) consisting of at least one core layer and at least one outer layer lying on either side of the core layer, and optionally having fastening and electrical connection elements, is provided,
ii) an adhesive layer B) is applied in the form of a plastic sheet or as a compound onto the sandwich element C),
iii) the solar cells are placed on the adhesive layer B) or embedded in the adhesive layer B), or a solar sheet is applied,
iv) a transparent plastic sheet A), which optionally comprises an adhesive layer B), and/or a transparent layer A) is applied onto solar cells,
v) the said layer structure is optionally pressed, optionally under the effect of temperature and/or optionally while applying a vacuum.

12. A method for producing solar modules according to claim 1, the method comprising:
i) a transparent plastic sheet A), which optionally comprises an adhesive layer B), and/or a transparent layer A) is provided,
ii) an adhesive layer B) is applied in the form of a plastic sheet or as a compound onto the layer A),
iii) the solar cells are placed on the adhesive layer B) or embedded in the adhesive layer B), or a solar sheet is applied,
iv) a sandwich element C) consisting of at least one core layer and at least one outer layer lying on either side of the core layer is applied onto the solar cells,
v) the said layer structure is optionally pressed, optionally under the effect of temperature and/or optionally while applying a vacuum.

13. A method for producing solar modules according to claim 1, the method comprising:
i) a prefabricated sheet module consisting of the layers A) and B), which already comprises the solar cells or the solar layer, is placed in a pressing tool,
ii) a sandwich element C), which preferably has not yet been pressed, is placed on the side of the sheet module which comprises the adhesive layer,
iii) pressing is carried out, optionally under the effect of temperature and/or optionally while applying a vacuum.

14. A method for producing solar modules according to claim 1, the method comprising:
i) an as yet unconnected sheet module is provided, the layer A) being placed in the pressing tool first, an adhesive layer B) subsequently being applied, and then these solar cells or the solar sheet being applied or embedded in the adhesive layer B),
ii) a further adhesive layer B) is optionally applied,
iii) a sandwich element C), which preferably has not yet been pressed, is placed on the side of the sheet module which comprises the adhesive layer,
iv) pressing is carried out, optionally under the effect of temperature and/or optionally while applying a vacuum.
